(19) United States
(12) Patent Application Publication
(10) Pub. No.: US 2011/0284276 A1
(43) Pub. Date: Nov. 24, 2011

(54) EPOXY RESIN COMPOSITION, AND PREPREG AND PRINTED CIRCUIT BOARD USING THE SAME

(76) Inventor: Hsien Te CHEN, Hsinchu County (TW)

(21) Appl. No.: 12/907,521

(22) Filed: Oct. 19, 2010

(30) Foreign Application Priority Data
May 21, 2010 (TW) 099116380

(51) Int. Cl. H05K 1/00; C08K 3/22

(52) U.S. Cl. 174/258; 523/458; 523/442

(57) ABSTRACT

Disclosed is an epoxy resin composition for printed circuit board, which includes (A) an epoxy resin; (B) a curing agent; (C) an inorganic filler including manganese oxide; and (D) a curing accelerator.

### BACKGROUND OF THE INVENTION

1. Field of the Invention

The present invention relates to an epoxy resin composition, and a prepreg and a printed wiring board using the epoxy resin composition, and more particularly to an epoxy resin composition which exhibits low dielectric constant (Dₖ) and low dissipation factor (D_{f}), and a prepreg impregnated with such a composition and a printed circuit board (PCB) manufactured by using such a prepreg.

2. The Prior Arts

Recently, the electronic devices such as computers and the communication devices, etc. are being more highly integrated and multilayered, and the mobile phones, the notebook computers, etc. are becoming more small-sized and lighter at weight. When the printed circuit boards mounted on these devices are becoming more integrated and compact, the superior heat resistance and dielectric reliability are required. With the development of high speed communication services, the signal delay and the transmission loss of high speed transmission circuit boards mounted on such communication devices are emerging as problem. Because the signal delay is proportional to the square root of the dielectric constant of the electrical insulating material, and the transmission loss is proportional to and the dissipation factor and the square root of the dielectric constant of the electrical insulating material, a material having low dielectric constant and dissipation factor is required for a high speed transmission circuit board.

In the conventional FR-4 printed circuit board, an epoxy resin composition comprising a brominated difunctional epoxy resin, a multifunctional epoxy resin, an amine based curing agent, an imidazole curing accelerator, etc. is used. The polar groups resulted from the reaction of the epoxy resin and the amine based curing agent increase the dielectric constant and the dissipation factor, so that it is impossible to obtain transmission characteristics sufficient for high speed transmission.

In order to solve this problem, Okada et al. (U.S. Pat. No. 4,798,762) disclose adding a filler material to resin to reduce the dielectric constant of a laminate. According to Okada et al., the preferred filler consists of hollow glass microspheres of 20-150 micrometers in diameter having a glass thickness of 0.5-2 micrometers. The use of hollow glass microspheres as a filler material to reduce the dielectric constant of the laminate, however, is not without disadvantages. Because the glass shell has a relatively high dielectric constant and somewhat offsets the very low dielectric constant gas which is incorporated within the hollow shell, a relatively high loading of the glass microspheres is required to provide a relatively low dielectric constant laminate. Also, because the hollow glass microspheres are buoyant and relatively hard to disperse, the additional equipment for continuous agitation is required to keep them suspended.

TW Pat. No. I264,446 further disclosed a prepreg which comprises a multicellular polymeric microspheres used as an alternative filler to the traditional glass microspheres, and the laminate made from such a prepreg has a relatively low and uniform dielectric constant, and improved thermal expansion characteristics. However, the process for manufacturing the polymeric microspheres with multicellular structure is complicated and the manufacturing cost is relatively high.

TW Pat. No. 413,659 further disclosed that the epoxy laminates, which incorporate up to 20 wt. % of talc particles, provide improved drilling performance, reduced dust formation, and improved coefficient of thermal expansion (CTE) in the Z direction, which reduces circuit failures due to differential thermal expansion.

From the above, it is known that the inorganic fillers are commonly used in reducing the dielectric properties or the coefficient of thermal expansion in the Z-axis of laminates. However, the more simplified process and lower cost for manufacturing the laminates incorporating the inorganic fillers should also be considered.

Accordingly, there still exists a need for providing a resin composition, which incorporates the inorganic filler in order to reduce the dielectric constant and the dissipation factor thereof, prepared by a low-cost and simplified process, and thus such a resin composition is useful in manufacturing a printed circuit board for high speed and high frequency transmission.

### SUMMARY OF THE INVENTION

Accordingly, the objective of the present invention is to provide an epoxy resin composition having low dielectric constant, low dissipation factor, superior heat resistance, and easy processability by use of a specific inorganic filler in order to solve the above-mentioned problems of the prior art, and also to provide a prepreg and a printed circuit board prepared from such an epoxy resin composition.

To achieve the above objective, the present invention provides an epoxy resin composition which comprises: (A) an epoxy resin having at least two epoxy groups in one molecule; (B) a curing agent; and (C) an inorganic filler comprising manganese oxide.

The epoxy resin composition of the present invention can preferably further include other inorganic fillers besides manganese oxide.

The epoxy resin composition of the present invention can preferably include a curing accelerator additionally.

The epoxy resin composition of the present invention can preferably include a silane coupling agent additionally.

The present invention further provides a prepreg produced by impregnating a reinforcing material with the epoxy resin composition of the present invention to form an impregnated substrate, and drying the impregnated substrate to a semi-cured state.

The present invention yet further provides a printed circuit board produced by laminating a particular number of the prepregs of the present invention to form a prepreg laminate, and forming a metal foil on at least one outermost layer of the prepreg laminate and heat pressure-molding the prepreg laminate to form a metal-clad laminate, and forming a circuit pattern on the metal foil of the metal-clad laminate.

The objective, characteristics, aspects, and advantages of the present invention will become more evident in the following detailed description.

### DETAILED DESCRIPTION OF THE PREFERRED EMBODIMENT

In one preferred embodiment of the present invention, the epoxy resin composition for the printed circuit board comprises: (A) an epoxy resin having at least two epoxy groups in one molecule; (B) a curing agent; (C) an inorganic filler comprising manganese oxide, wherein the manganese oxide has an average particle diameter of less than 150 μm, and preferably between 0.5 and 50 μm; (D) a curing accelerator; and (E) a silane coupling agent.

The epoxy resin (A) used in the epoxy resin composition of the present invention has at least two epoxy groups in one molecule. Examples of the epoxy resin used in the present invention include, but are not limited to, bisphenol A epoxy resin such as brominated bisphenol A epoxy resin, bisphenol F epoxy resin, bisphenol S epoxy resin, phenol novolak epoxy resin such as DOPO-PNE (which is obtained by reacting 10-dihydro-9-oxa-10-phosphahenanthrene-10-oxide (DOPO) with phenol novolac epoxy resin (PNE)), and cresol novolak epoxy resin. These above-mentioned epoxy resins can be used singly or in combination of two or more of them.

The curing agent (B) used in the epoxy resin composition of the present invention can be any compound that can undergo a cross-linking reaction with the epoxy resin to form an interpenetrating polymeric network. Examples of the curing agent used in the present invention include, but are not limited to, amines, phenolics, carboxylic acid anhydrides, and mercaptans. These curing agents can be used singly or in combination of two or more of them. Preferred curing agents include primary amines such as 4,4′-diaminodiphenylsulfone (DDS), and dicyandiamide (DICY). The curing agent is present in the epoxy resin composition of the present invention in an amount from 10 to 30 parts by weight, based on 100 parts by weight of the epoxy resin.

The inorganic filler (C) used in the epoxy resin composition of the present invention comprises manganese oxide, and in order to impart flatness and good processability to the prepreg, the manganese oxide preferably has an average particle diameter of less than 150 μm and more preferably between 0.5 and 50 μm. The manganese oxide used in the present invention comprises manganese (II, III) oxide (Mn₃O₄), manganese (IV) oxide (MnO₂), or mixture thereof. The manganese oxide is present in the epoxy resin composition of the present invention in an amount from 0.1 to 10 parts by weight and preferably from 0.3 to 3 parts by weight, based on 100 parts by weight of the epoxy resin.

One or more other inorganic fillers besides manganese oxide can be optionally added to the epoxy resin composition of the present invention in order to impart additional flame retardancy, heat resistance and humidity resistance to the epoxy resin composition. Examples of the inorganic filler optionally used in the present invention include, but are not limited to, silica, alumina, aluminium hydroxide, mica, talc, and kaolin clay. Preferred inorganic fillers include silica, and alumina.

The curing accelerator (D) used in the epoxy resin composition of the present invention can be any compound that is used for accelerating the curing of an epoxy resin. Examples of the curing accelerator used in the present invention include, but are not limited to, boron trifluoride-ethylamine complex, and boron trichloride-ethylamine complex. These two curing accelerators can be used singly or in combination. Other suitable accelerators include imidazoles such as 2-methylimidazole, 2-ethyl-4-methylimidazole, and 2-phenylimidazole. The amount of curing accelerator used is dependent on the type of epoxy resin, the type of curing agent, and the type of curing accelerator. The curing accelerator is present in the epoxy resin composition of the present invention in an amount from 0.1 to 1 parts by weight, based on 100 parts by weight of the epoxy resin.

The silane coupling agents (E) used in the epoxy resin composition of the present invention can provide improved dispersion of the inorganic fillers in the epoxy resin composition and can optimize the electrical and physical properties of the epoxy resin composition. Examples of the silane coupling agent used in the present invention include, but are not limited to, Dow Corning® product Z-6300 Silane, Z-6076 Silane, and Z-6040 Silane. The preferred one is Dow Corning® product Z-6040 Silane. The silane coupling agent is present in the epoxy resin composition of the present invention in an amount from 0.1 to 1 parts by weight, based on 100 parts by weight of the epoxy resin.

If necessary, various other additives such as toughener, flame retardant, pigments, and emulsifiers can also be used in the epoxy resin composition of the present invention.

One or more solvents can be used for preparing the epoxy resin composition varnish in the present invention in order to provide resin solubility, and control resin viscosity. Examples of the solvents used in the present invention include, but are not limited to, acetone, methylethylketone, propylene glycol methyl ether, cyclohexanone, and propylene glycol methyl ether acetate. These solvents can be used singly or in combination of two or more of them. Preferred solvents include methylethylketone, and propylene glycol methyl ether acetate. The solvent is present in the epoxy resin composition of the present invention in an amount from about 50 to 70 parts by weight, based on 100 parts by weight of the epoxy resin.

The epoxy resin composition of the present invention can be prepared by blending the components (A), (B), (C), (D), and (E), and then agitating the mixture uniformly, for example, in a mixer or blender.

The epoxy resin composition varnish of the present invention is prepared by dissolving or dispersing the obtained epoxy resin composition in a solvent.

A reinforcing material is impregnated with the resin varnish to form an impregnated substrate, and then the impregnated substrate is heated in a dryer at 150 to 180° C. for 2 to 10 minutes to give a prepreg in a semi-cured state (B-stage). Examples of the reinforcing material used in the present invention include, but are not limited to, glass fiber cloth, glass paper and glass mat, and also, kraft paper and linter paper.

A metal-clad laminate is prepared by laminating a particular number of the prepregs thus obtained, placing a metal foil additionally on at least one outermost layer and molding the composite under heat and pressure. As for the heat pressure-molding condition, the temperature is 160 to 190° C., the molding pressure is 10 to 30 kg/cm², and the molding time is 30 to 120 minutes. Then, a metal-clad laminate used for production of printed circuit boards is formed under such heat and pressure conditions. Examples of the metal foils used in the present invention include, but are not limited to, copper foil, aluminum foil, and stainless steel foil.

A circuit pattern formed on the surface of the metal-clad laminate is obtained by leaving circuit pattern-forming regions and removing the other regions thereof by using the subtractive process, otherwise known as the etching process. In this way, a printed wiring board carrying a circuit on the surface is obtained.

Hereinafter, the present invention will be described in more detail with reference to Examples. It should be understood that the present invention is not restricted at all by these Examples.

### <Preparation of Epoxy Resin Composition Varnishes>

### EXAMPLE 1

100 parts by weight of brominated bisphenol A novolac epoxy resin (HEXION 1134, manufactured by Hexion Specialty Chemicals Inc., epoxy equivalence of 390 to 430 g/eq, bromine atom content: 18%), 20 parts by weight of diaminodiphenylsulfone (hydroxyl group equivalence of 62 g/eq), 1 part by weight of Mn₃O₄ (manufactured by Unique Enterprises, Inc.), 30 parts by weight of silica (925, manufactured by Sibelco, Inc.), 0.5 parts by weight of boron trifluoride-ethylamine complex (manufactured by Hashimoto Chem. Ind. Co.), and 0.3 parts by weight of silane coupling agent (Z-6040, Dow Corning) were mixed together by a mixer at room temperature for 60 minutes, and then the obtained mixture was dissolved in 60 parts by weight of methylethylketone, followed by stirring in a disperser at room temperature for 120 minutes to give the epoxy resin composition varnish.

### EXAMPLE 2

100 parts by weight of DOPO-CNE (CCP 330, manufactured by Chang Chun Plastics Co., epoxy equivalence of 350 to 390 g/eq), 18 parts by weight of diaminodiphenylsulfone (hydroxyl group equivalence of 62 g/eq), 1 part by weight of Mn₃O₄ (manufactured by Unique Enterprises, Inc.), 30 parts by weight of silica (925, manufactured by Sibelco, Inc.), 0.5 parts by weight of boron trifluoride-ethylamine complex (manufactured by Hashimoto Chem. Ind. Co.), and 0.3 parts by weight of silane coupling agent (Z-6040, Dow Corning) were mixed together by a mixer at room temperature for 60 minutes, and then the obtained mixture was dissolved in 60 parts by weight of methylethylketone, followed by stirring in a disperser at room temperature for 120 minutes to give the epoxy resin composition varnish.

### EXAMPLE 3

50 parts by weight of bisphenol F novolac epoxy resin (KOLON 8100, manufactured by Kolon Chemical Co., epoxy equivalence of 160 to 200 g/eq), 50 parts by weight of DOPO-CNE (CCP 330, manufactured by Chang Chun Plastics Co., epoxy equivalence of 350 to 390 g/eq), 20 parts by weight of diaminodiphenylsulfone (hydroxyl group equivalence of 62 g/eq), 1 part by weight of Mn₃O₄ (manufactured by Unique Enterprises, Inc.), 30 parts by weight of silica (925, manufactured by Sibelco, Inc.), 0.5 parts by weight of boron trifluoride-ethylamine complex (manufactured by Hashimoto Chem. Ind. Co.), and 0.3 parts by weight of silane coupling agent (Z-6040, Dow Corning) were mixed together by a mixer at room temperature for 60 minutes, and then the obtained mixture was dissolved in 60 parts by weight of methylethylketone, followed by stirring in a disperser at room temperature for 120 minutes to give the epoxy resin composition varnish.

### EXAMPLE 4

100 parts by weight of DOPO-CNE (CCP 330, manufactured by Chang Chun Plastics Co., epoxy equivalence of 350 to 390 g/eq), 18 parts by weight of diaminodiphenylsulfone (hydroxyl group equivalence of 62 g/eq), 5 part by weight of Mn₃O₄ (manufactured by Unique Enterprises, Inc.), 30 parts by weight of silica (925, manufactured by Sibelco, Inc.), 0.5 parts by weight of boron trifluoride-ethylamine complex (manufactured by Hashimoto Chem. Ind. Co.), and 0.3 parts by weight of silane coupling agent (Z-6040, Dow Corning) were mixed together by a mixer at room temperature for 60 minutes, and then the obtained mixture was dissolved in 60 parts by weight of methylethylketone, followed by stirring in a disperser at room temperature for 120 minutes to give the epoxy resin composition varnish.

### EXAMPLE 5

100 parts by weight of brominated bisphenol A novolac epoxy resin (HEXION 1134, manufactured by Hexion Specialty Chemicals Inc., epoxy equivalence of 390 to 430 g/eq, bromine atom content: 18%), 20 parts by weight of diaminodiphenylsulfone (hydroxyl group equivalence of 62 g/eq), 3 part by weight of Mn₃O₄ (manufactured by Unique Enterprises, Inc.), 0.5 parts by weight of boron trifluoride-ethylamine complex (manufactured by Hashimoto Chem. Ind. Co.), and 0.3 parts by weight of silane coupling agent (Z-6040, Dow Corning) were mixed together by a mixer at room temperature for 60 minutes, and then the obtained mixture was dissolved in 60 parts by weight of methylethylketone, followed by stirring in a disperser at room temperature for 120 minutes to give the epoxy resin composition varnish.

### COMPARATIVE EXAMPLE 1

100 parts by weight of brominated bisphenol A novolac epoxy resin (HEXION 1134, manufactured by Hexion Specialty Chemicals Inc., epoxy equivalence of 390 to 430 g/eq, bromine atom content: 18%), 20 parts by weight of diaminodiphenylsulfone (hydroxyl group equivalence of 62 g/eq), 30 parts by weight of silica (925, manufactured by Sibelco, Inc.), 0.5 parts by weight of boron trifluoride-ethylamine complex (manufactured by Hashimoto Chem. Ind. Co.), and 0.3 parts by weight of silane coupling agent (Z-6040, Dow Corning) were mixed together by a mixer at room temperature for 60 minutes, and then the obtained mixture was dissolved in 60 parts by weight of methylethylketone, followed by stirring in a disperser at room temperature for 120 minutes to give the epoxy resin composition varnish.

### COMPARATIVE EXAMPLE 2

100 parts by weight of DOPO-CNE (CCP 330, manufactured by Chang Chun Plastics Co., epoxy equivalence of 350 to 390 g/eq), 18 parts by weight of diaminodiphenylsulfone (hydroxyl group equivalence of 62 g/eq), 30 parts by weight of silica (925, manufactured by Sibelco, Inc.), 0.5 parts by weight of boron trifluoride-ethylamine complex (manufactured by Hashimoto Chem. Ind. Co.), and 0.3 parts by weight of silane coupling agent (Z-6040, Dow Corning) were mixed together by a mixer at room temperature for 60 minutes, and then the obtained mixture was dissolved in 60 parts by weight of methylethylketone, followed by stirring in a disperser at room temperature for 120 minutes to give the epoxy resin composition varnish.

### <Preparation of Prepregs>

The 7628 glass fiber cloths (product of Nitto Boseki Co., Ltd.) were respectively impregnated with the resin varnish obtained in Examples 1 to 5 and Comparative Examples 1 to 2 at room temperature, and followed by heating the impregnated glass fiber cloths at approximately 180° C. for 2 to 10 minutes to remove the solvent in the resin varnish (here, the resulting epoxy resin compositions were semi-cured) to obtain the prepregs of Examples 1 to 5 and Comparative Examples 1 to 2.

### <Preparation of Printed Circuit Boards >

Four prepregs (300 mm×510 mm) of Example 1 were held and laminated between two copper foils (thickness: 1 oz, product of Nikko Gould Foil Co., Ltd.), to give a laminate. The laminate was then molded under the heating/pressurization condition of the temperature of 180° C. (the programmed heating rate of 2.0° C./minutes) and the pressure of 15 kg/cm² (an initial pressure: 8 kg/cm²) for 60 minutes, to give a copper-clad laminate for printed circuit board. Then, a circuit pattern was formed on the surface of the copper-clad laminate by leaving circuit pattern-forming regions and removing the other regions thereof by etching, and thereby a printed circuit board carrying a circuit on the surface was obtained.

The copper-clad laminates and the printed circuit boards for Examples 2 to 5 and Comparative Examples 1 to 2 were respectively obtained in the same way as the above-mentioned method for producing the copper-clad laminate and the printed circuit board of Example 1.

The properties of the copper-clad laminates obtained in Examples 1 to 5 and Comparative Examples 1 to 2 were respectively determined by the following evaluation tests.

### [Water Absorption]

The standard pressure cooker test was done at 121° C., 100% relative humidity, and 2 atmospheric pressures for 1 hour.

### [Solder Floating]

The sample was kept floating on a solder bath of 288° C. for the time indicated in Table 1 and, then blister of the sample was visually observed.

### [Peeling Strength of Copper Foil]

One oz of copper foil on the copper-clad laminate was peeled off for determination of its 90° peel strength (JIS-C-6481).

### [Glass Transition Temperature]

The glass transition temperature (Tg) was measured as peak temperature of tan 8 at 1 Hz by a dynamic mechanical analyzer, manufactured by Seiko Instruments, Inc.

### [Thermal Decomposition Temperature]

A resin was separated from a copper-clad laminate and analyzed in a thermogravimetric and differential thermal analyzer (TG-DTA). The programmed heating rate was 5° C./minute. The thermal decomposition temperature was a temperature at which the weight of the sample decreased by 5% from the initial weight.

### [Flame Retardancy]

The flame retardancy of a copper-clad laminate was evaluated by the method specified in UL 94. The UL 94 is a vertical burn test that classifies materials as V-0, V-1 or V-2.

### [Dielectric Properties]

The dielectric constant and the dissipation factor at 1 GHz were measured according to the procedures of ASTM D150-87.

The epoxy resin compositions and the test results of the test items above are summarized in Table 1.

TABLE 1
Epoxy Resin Compositions

| Relative to 100 parts by | | Example | Example | Example | Example | Example | Comparative | Comparative |
|---|---|---|---|---|---|---|---|---|
| weight of the epoxy resin | | 1 | 2 | 3 | 4 | 5 | Example 1 | Example 2 |
| Epoxy resin | brominated | 100 | — | — | — | 100 | 100 | — |
| | bisphenol | | | | | | | |
| | A epoxy resin | | | | | | | |
| | bisphenol F epoxy | — | — | 50 | — | — | — | — |
| | resin | | | | | | | |
| | DOPO-PNE | — | 100 | 50 | 100 | — | — | 100 |
| Curing agent | DDS | 20 | 18 | 20 | 18 | 20 | 20 | 18 |
| Inorganic filler 1 | Mn₃O₄ | 1 | 1 | 1 | 5 | 3 | 0 | 0 |
| Inorganic filler 2 | Silica | 30 | 30 | 30 | 30 | 0 | 30 | 30 |
| Curing | trifluoride- | 0.5 | 0.5 | 0.5 | 0.5 | 0.5 | 0.5 | 0.5 |
| accelerator | ethylamine | | | | | | | |
| | complex | | | | | | | |
| Coupling agent | silane coupling | 0.3 | 0.3 | 0.3 | 0.3 | 0.3 | 0.3 | 0.3 |
| | agent | | | | | | | |
| Solvent | MEK | 60 | 60 | 60 | 60 | 60 | 60 | 60 |

Test Results

| | | | Example | Example | Example | Example | Example | Comparative | Comparative |
|---|---|---|---|---|---|---|---|---|---|
| Properties | Conditions | Unit | 1 | 2 | 3 | 4 | 5 | Example 1 | Example 2 |
| Water absorption | PCT 121° C. | % | 0.153 | 0.169 | 0.151 | 0.168 | 0.152 | 0.151 | 0.170 |
| | for 1 hr | | | | | | | | |
| Solder floating | 288° C. | min | >10 | >10 | >10 | >10 | >10 | >10 | >10 |
| Peeling strength | | lb/in | 8.9 | 8.2 | 8.3 | 8.4 | 8.8 | 8.8 | 8.5 |
| (1 oz) | | | | | | | | | |
| Glass transition | DMA | ° C. | 153 | 163 | 147 | 162 | 153 | 153 | 164 |
| temperature | | | | | | | | | |
| Thermal | TGA | ° C. | 369 | 381 | 374 | 380 | 368 | 368 | 382 |
| decomposition | | | | | | | | | |
| temperature | | | | | | | | | |
| Flame retardancy | rating | UL94 | V-0 | V-0 | V-0 | V-0 | V-0 | V-0 | V-0 |
| Dielectric | Dk at 1 GHz | | 4.54 | 4.68 | 4.61 | 4.68 | 4.55 | 4.55 | 4.71 |
| constant | | | | | | | | | |
| Dissipation | Df at 1 GHz | | 0.012 | 0.013 | 0.015 | 0.014 | 0.012 | 0.022 | 0.018 |
| factor | | | | | | | | | |

As seen from Table 1, the copper-clad laminates obtained according to the present invention (Examples 1 to 5) have the well-balanced properties and every required performance for use as printed circuit boards. These copper-clad laminates have superior dielectric characteristics with low dielectric constant and low dissipation factor and have superior glass transition temperature, heat resistance, peeling strength of copper foil, and easy processability, and thus being useful as a PCB substrate for high frequency applications. Although silica was not used in the epoxy resin composition in the case of Example 5, the copper-clad laminate obtained according to Example 5 still has the required performance for use as printed circuit boards. The dissipation factor values of the copper-clad laminates of the present invention are not greater than 0.015. As compared with Examples 1 to 5 of the present invention, the dissipation factor values of the copper-clad laminates of Comparative Examples 1 and 2 are not less than 0.018. Obviously, when manganese oxide as inorganic filler is added to the epoxy resin composition, the dissipation factor of the copper-clad laminates made from such an epoxy resin composition becomes smaller.

Accordingly, the copper-clad laminates or the printed circuit boards of the present invention prepared from the epoxy resin compositions containing manganese oxide having an average particle diameter of less than 150 μm are not only excellent in dielectric properties and heat resistance, but also can be devoid of the disadvantages of the above-mentioned laminates containing the conventional inorganic fillers. Furthermore, the epoxy resin composition of the present invention, which incorporates manganese oxide as inorganic filler, is manufactured by a low-cost and simplified process.

It is contemplated that various modifications may be made to the compositions, prepregs, laminates and printed circuit boards of the present invention without departing from the spirit and scope of the invention as defined in the following claims.

What is claimed is:

1. An epoxy resin composition comprising:
(A) an epoxy resin having at least two epoxy groups in one molecule;
(B) a curing agent; and
(C) an inorganic filler comprising manganese oxide.

2. The epoxy resin composition as claimed in claim 1, wherein the manganese oxide has an average particle diameter of less than 150 μm.

3. The epoxy resin composition as claimed in claim 1, wherein the manganese oxide comprises manganese (II, III) oxide, manganese (IV) oxide, or mixture thereof.

4. The epoxy resin composition as claimed in claim 1, the manganese oxide is present in an amount of 0.1 to 10 parts by weight, based on 100 parts by weight of the epoxy resin.

5. The epoxy resin composition as claimed in claim 1, the manganese oxide is present in an amount of 0.3 to 3 parts by weight, based on 100 parts by weight of the epoxy resin.

6. The epoxy resin composition as claimed in claim 1, wherein the inorganic filler further comprises at least one of silica, alumina, aluminium hydroxide mica, talc, and kaolin clay.

7. The epoxy resin composition as claimed in claim 1, wherein the epoxy resin is selected from the group consisting of bisphenol A epoxy resin, bisphenol F epoxy resin, bisphenol S epoxy resin, phenol novolak epoxy resin, and cresol novolak epoxy resin.

8. The epoxy resin composition as claimed in claim 7, the bisphenol A epoxy resin includes a brominated bisphenol A epoxy resin.

9. The epoxy resin composition as claimed in claim 7, the phenol novolak epoxy resin includes DOPO-PNE which is obtained by reacting 10-dihydro-9-oxa-10-phosphahenanthrene-10-oxide (DOPO) with phenol novolac epoxy resin (PNE).

10. The epoxy resin composition as claimed in claim 1, wherein the curing agent is present in an amount of 10 to 30 parts by weight, based on 100 parts by weight of the epoxy resin.

11. The epoxy resin composition as claimed in claim 1, wherein the curing agent is selected from the group consisting of amines, phenolics, carboxylic acid anhydrides, and mercaptans.

12. The epoxy resin composition as claimed in claim 11, wherein the amines include diaminodiphenylsulfone.

13. The epoxy resin composition as claimed in claim 1, further comprising a curing accelerator.

14. The epoxy resin composition as claimed in claim 13, wherein the curing accelerator is present in an amount of 0.1 to 1 parts by weight, based on 100 parts by weight of the epoxy resin.

15. The epoxy resin composition as claimed in claim 13, wherein the curing accelerator includes boron trifluoride-ethylamine complex, boron trichloride-ethylamine complex, or mixture thereof.

16. The epoxy resin composition as claimed in claim 1, further comprising a silane coupling agent.

17. The epoxy resin composition as claimed in claim 1, wherein the silane coupling agent is present in an amount of 0.1 to 1 parts by weight, based on 100 parts by weight of the epoxy resin.

18. A prepreg produced by impregnating a reinforcing material with the epoxy resin composition according to claim 1 to form an impregnated substrate, and drying the impregnated substrate to a semi-cured state.

19. A printed circuit board produced by laminating a particular number of the prepregs according to claim 18 to form a prepreg laminate, placing a metal foil on at least one outermost layer of the prepreg laminate and heat pressure-molding the prepreg laminate to form a metal-clad laminate, and forming a circuit pattern on the metal foil of the metal-clad laminate.
